(19) United States
(12) Patent Application Publication
(10) Pub. No.: US 2016/0322594 A1
(43) Pub. Date: Nov. 3, 2016

(54) ORGANIC ELECTROLUMINESCENT DEVICE, LIGHTING APPARATUS, AND LIGHTING SYSTEM

(71) Applicant: Kabushiki Kaisha Toshiba, Minato-ku (JP)

(72) Inventors: Hayato KAKIZOE, Kawasaki (JP); Daimotsu KATO, Fuchu (JP); Tomoaki SAWABE, Tokyo (JP); Keiji SUGI, Fujisawa (JP); Akio AMANO, Machida (JP); Tomio ONO, Yokohama (JP); Shintaro ENOMOTO, Yokohama (JP)

(73) Assignee: Kabushiki Kaisha Toshiba, Minato-ku (JP)

(21) Appl. No.: 15/205,455

(22) Filed: Jul. 8, 2016

Related U.S. Application Data
(63) Continuation of application No. PCT/JP2014/050107, filed on Jan. 8, 2014.

(51) Int. Cl. H01L 51/52; H05B 33/08

(52) U.S. Cl. CPC H01L 51/5203; H01L 51/5253; H05B 33/0896

(57) ABSTRACT

According to an embodiment, an organic electroluminescent device includes a first electrode that is optically transparent and has a first region and a second region; an insulation layer that has insulation parts formed of a translucent insulation material on the first and second regions, the insulation parts arranged per unit of surface area are equal in number between the first and second regions; an organic layer provided on at least the first region of the first electrode via the insulation layer; and a second electrode formed on the organic layer, having conductive parts each of which is light-reflective and openings. Each of the openings overlaps at least two of the insulation parts.

### CROSS-REFERENCE TO RELATED APPLICATIONS

This is a Continuation application of PCT Application No. PCT/JP2014/050107, filed Jan. 8, 2014, the entire contents of which are incorporated herein by reference.

### FIELD

Embodiments described herein relate generally to an organic electroluminescent device, a lighting apparatus, and a lighting system.

### BACKGROUND

Lighting apparatuses and lighting systems include, for example, a power supply, and one or more organic electroluminescent devices connected to the power supply. The organic electroluminescent device includes, for example, a support board, a first electrode placed on the support board, a second electrode, and an organic layer sandwiched between the first and second electrodes. When the organic layer receives positive holes from the first electrode which is an anode and receives electrons from the second electrode which is a cathode, electrons and positive holes are coupled within the organic layer to emit light.

For example, when the first electrode is formed of a translucent conductive material, and the second electrode is formed of a conductive material with a high reflective rate, light emitted to the second electrode side is reflected toward the first electrode side by the second electrode in the organic layer, and the light becomes a bottom-emission organic electroluminescent device which emits light toward the support board side.

When an opening is defined in the second electrode of the organic electroluminescent device, a light emitting area where light is emitted toward the support board side when energized, and a transmission region where a transmitted image at one side can be viewed from the other side of the support board through the opening are formed. For example, with the second electrode that is formed to have an opening of a stripe pattern or a grid pattern, when a light emitting surface is viewed upon being energized, a transmitted image cannot be viewed due to an optical illusion caused by the high luminance of the emitted light. When not being energized, a non-light emitting surface side can be viewed from the light emitting surface side, and vise versa.

### BRIEF DESCRIPTION OF THE DRAWINGS

FIG. 1 is a schematic cross-sectional view of an organic electroluminescent device according to the first embodiment.

FIG. 2 is a plane figure roughly illustrating an example configuration of an insulation layer and a second electrode in the organic electroluminescent device according to the first embodiment.

FIG. 3 illustrates an example of the relationship between the covering rate of the insulation layers within a second electrode and an emission surface area rate.

FIG. 4A illustrates an example of positions where the insulation parts are arranged.

FIG. 4B illustrates an example of positions where the insulation parts are arranged.

FIG. 5A illustrates an example of positions where the insulation parts are arranged.

FIG. 5B illustrates an example of positions where the insulation parts are arranged.

FIG. 6 illustrates an example of positions where the insulation parts are arranged.

FIG. 7 illustrates an example of positions where the insulation parts are arranged.

FIG. 8 is a cross-sectional view of an organic electroluminescent device according to the first embodiment.

FIG. 9 is a schematic diagram showing a lighting apparatus according to the second embodiment.

FIG. 10A is a schematic diagram illustrating an example configuration of a lighting system according to the third embodiment.

FIG. 10B is a schematic diagram illustrating an example configuration of a lighting system according to the third embodiment.

### DETAILED DESCRIPTION

In general, according to an embodiment, an organic electroluminescent device includes a first electrode that is optically transparent and has a first region and a second region; an insulation layer that has a plurality of insulation parts formed of a translucent insulation material on the first and second regions, the insulation parts arranged per unit of surface area are equal in number between the first and second regions; an organic layer provided on at least the first region of the first electrode via the insulation layer; and a second electrode formed on the organic layer, having a plurality of conductive parts each of which is light-reflective and a plurality of openings. Each of the openings overlaps at least two of the insulation parts.

Hereinafter, the organic electroluminescent device, lighting apparatus, and lighting system according to the embodiments will be described with reference to the drawings. It should be noted that the drawings are schematic or conceptual, and the relations between thickness and width, the size or ratio, etc. in the drawings may be different in actual implementation. In addition, the size or ratio, etc. of each element may be different between the drawings. In the specification and the drawings, units previously specified by the same reference numbers carry out the same operation, and a detailed explanation thereof may be suitably omitted.

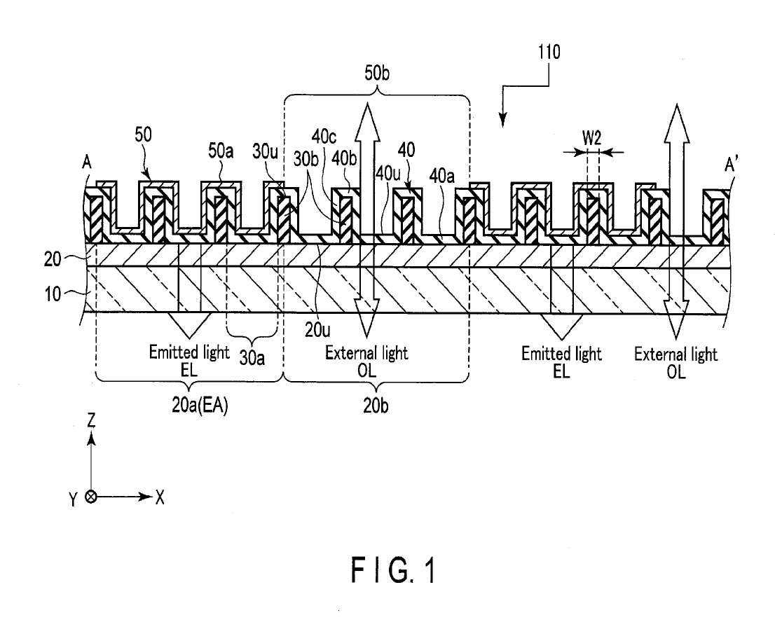

FIG. 1 roughly illustrates an example configuration of an insulation layer and a second electrode in the organic electroluminescent device according to the embodiment.

The organic electroluminescent device 110 according to the present embodiment includes a first electrode 20, an insulation layer 30, an organic light emitting layer (organic layer) 40 and a second electrode 50. The first electrode 20 is optically transparent, and has a first region 20a and a second region 20b. The insulation layer 30 is formed of a translucent insulation material on the first region 20a and the second region 20b. The same number of insulation layers 30 are provided per unit of surface area for the first region 20a and the second region 20b. The organic light emitting layer 40 is provided on at least the first region 20a of the first electrode 20 via the insulation layer 30. The second electrode 50 is formed on the organic light emitting layer 40 provided on the first region 20a, and has a light-reflecting conductive part 50a and an opening 50b. The opening 50b overlaps at least two insulation layers 30.

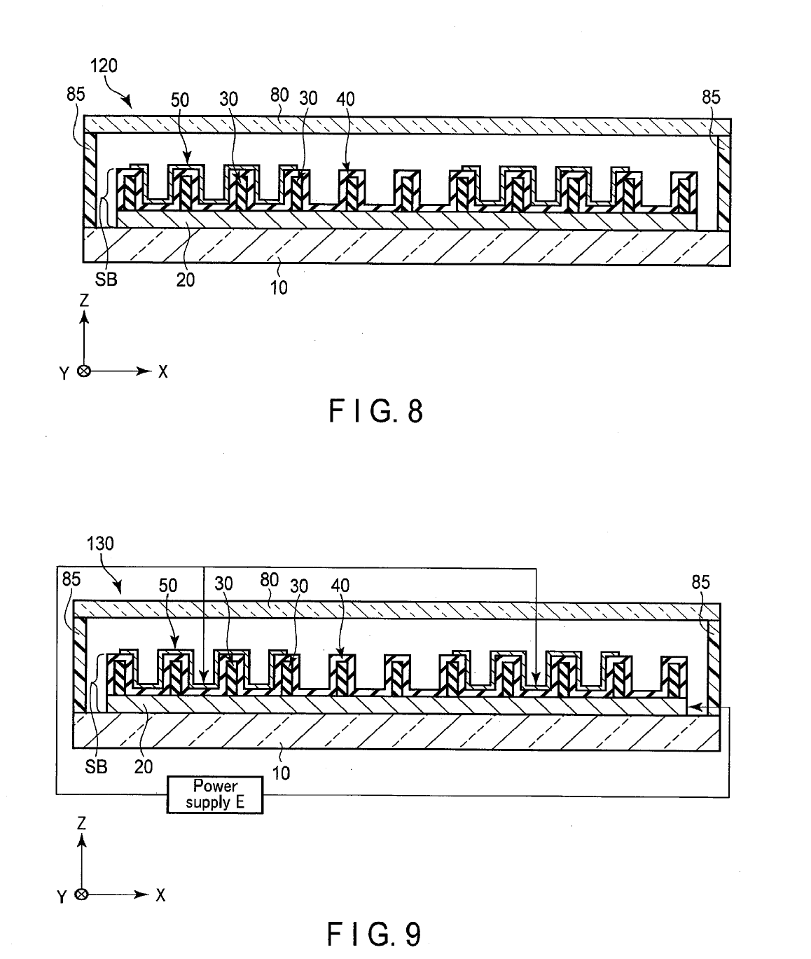

The organic electroluminescent device 110 may further include a first support board 10 and a second support board 80 (shown in FIGS. 8 and 9). The organic electroluminescent device 110 including the first support board 10 and the second support board 80 will be explained below.

The first support board 10 is a planar support board formed of an insulation material such as glass, quartz, plastic, and resin. For example, a transparent resin such as polyethylene terephthalate, polycarbonate, polymethyl methacrylate, polypropylene, polyethylene, amorphous polyolefin, and fluorine resin may be used for the first support board 10.

In the following description, the direction essentially parallel to the main surface (support surface of multiple layers) of the first support board 10 is a first direction X, and mutually intersecting this direction is a second direction Y, and the direction orthogonal to the main surface of the first support board 10 is indicated as a third direction Z. In the present embodiment, the first direction X and the second direction Y are orthogonal to each other.

The first electrode 20 is provided on the first support board 10. The first electrode 20 has a main surface facing the main surface of the first support board 10. The main surface of the first electrode 20 is essentially parallel to the main surface of the first support board 10. For example, the first electrode 20 is a transparent electrode.

The first electrode 20 includes an oxide including at least one element selected from the group consisting of In, Sn, Zn, and Ti, for example. The first electrode 20 may be formed, for example, of an indium oxide film, a zinc oxide film, a tin oxide film, an indium tin oxide (ITO) film, a fluorine-doped tin oxide (FTO) film, a film created by using a conductive glass including an indium zinc oxide (for example, NESA), and a film including gold, platinum, silver, or copper. The first electrode 20 acts as an anode, for example. The first electrode 20 may be formed by materials other than the above-listed materials. Part of the first electrode 20 may be extended to an end of the first support board 10 to be connected to a terminal electrically connected to the power supply (not shown in the drawings).

The insulation layer 30 is provided on the first electrode 20. For example, the insulation layer 30 includes a plurality of insulation parts 30b arranged in the first direction X and the second direction Y, and an opening 30a defined between adjacent insulation parts 30b. Part of the first electrode 20 is exposed from the opening 30a of the insulation layer 30. In this example, each of the insulation parts 30b are arranged on the top surface of the first electrode 20 as an island pattern. The insulation parts 30b are provided in the first region 20a and the second region 20b with the same ratio. For example, the number of insulation parts 30b of the insulation layer 30 per unit of surface area is 100/cm² in both the first region 20a and the second region 20b. The difference in the number of insulation parts 30b per unit of surface area is less than 10% between the first region 20a and the second region 20b. For example, the insulation layer 30 is transparent.

The insulation parts 30b are pillars extending in the third direction Z, for example. The cross-sectional shape of the plane defined by the first direction X and the second direction Y of the insulation parts 30b is, for example, a circle, a polygonal such as a rectangle, or a polygonal with rounded corners. The cross-sectional shape of the insulation parts 30b may have a maximum length of a range from 1 μm to 50 μm. The maximum length is a largest length of line segments defined by a certain point and another point on the outer peripheral of the cross-section. For example, the maximum length of a circle is equal to a diameter, and the maximum length of a rectangle is a diagonal line connected corner-to-corner.

The insulation layer 30 is formed, for example, of a resin material such as a acrylic resin and a polyimide resin. Otherwise, an inorganic material such as a silicon oxide film (e.g., SiO₂), a silicon nitride film (e.g., SiN), and a silicon oxinitride film may be used. The insulation layer 30 may be formed by materials other than the above-listed materials. The insulation layer 30 is also placed in the transmission region (region overlapping the opening 50b of the second electrode 50). Accordingly, it is preferable that the insulation layer 30 is formed of a material having a high translucent rate. In this embodiment, the thickness of the insulation layer 30 (height in the third direction Z) is within a range of about 500 nm to about 4 μm.

The organic light emitting layer 40 may be provided not only in the first region 20a, but also in the second region 20b of the first electrode 20. The organic light emitting layer 40 includes a first part 40a provided on the first electrode 20 exposed from the insulation layer 30, a second part 40b provided on the insulation layer 30, and a third part 40c which is a remaining part. The third part 40c extends along a side surface of the insulation parts 30b, and connects the first part 40a and the second part 40b. The organic light emitting layer 40 has translucent properties. For example, The organic light emitting layer 40 has translucent properties when the light is off. For example, the organic light emitting layer 40 is provided continuously on at least part of each of the plurality of insulation parts 30b and on the plurality of first electrodes 20.

The thickness of the organic light emitting layer 40 (length along the Z axis direction) is smaller than the thickness of the insulation layer 30. The distance in the Z axis direction between an upper surface 40u of the first part 40a of the organic light emitting layer 40 and an upper surface 20u of the first electrode 20 is shorter than the distance in the Z axis direction between an upper surface 40u of the second part 40b of the organic light emitting layer 40 and the upper surface 20u of the first electrode 20. The upper surface 40u of the first part 40a is placed below an upper surface 30u of the insulation parts 30b.

The organic light emitting layer 40 includes a light emitting layer. The organic light emitting layer 40 may further include at least one of a positive hole injection layer, a positive hole transport layer, an electron transport layer, and an electron injection layer. The organic light emitting layer 40 has a stacked structure, for example (not shown in the drawings). When the organic light emitting layer 40 receives positive holes from the first electrode 20 which is an anode and receives electrons from the second electrode 50 which is a cathode, electrons and positive holes are coupled within the organic light emitting layer 40 to emit light. Light emission is performed by using energy emission when radiative deactivation occurs in an exciton. In the present embodiment, the organic light emitting layer 40 emits light including components having a wavelength of visible light. For example, light emitted from the organic light emitting layer 40 is substantially white light. That is, light emitted from the organic electroluminescent device is white light. The “white light” is essentially white, and the white light includes red, yellow, green, blue and purple wavelengths.

The second electrode 50 includes the conductive part 50a and the opening 50b. The conductive part 50a is provided on at least part of the first part 40a. In this example, the second electrode 50 includes a plurality of conductive parts 50a and a plurality of openings 50b. For example, the plurality of conductive part 50a extend in the Y axis direction and are arranged in the X axis direction. For example, the plurality of openings 50b extend in the Y axis direction and are arranged in the X axis direction. The first part 40a is provided between the conductive part 50a of the second electrode 50 and the first electrode 20 exposed from the opening 30a of the insulation layer 30. The light-reflective rate of the conductive part 50a of the second electrode 50 is higher than the reflective rate of the first electrode 20. In the present embodiment, “light-reflective property” indicates the state having the light-reflective rate higher than that of the first electrode 20.

The first part 40a is electrically connected to the first electrode 20 and the second electrode 50 in the first region 20a. In the present embodiment, “electrically connected” includes a direct connection and indirect connection via another conductive member.

The second electrode 50 is formed of a material having a high light-reflective rate, for example, and reflects light emitted by the organic light emitting layer 40 toward the first support board 10 side. The second electrode 50 is, for example, formed of a metallic material such as copper, aluminum, silver, magnesium, and calcium, or a multi-layer metallic material in which multiple metallic materials are combined. In addition, an alloy of silver and magnesium may be used. Furthermore, calcium may be added to the alloy. The second electrode 50 acts as a cathode, for example. The second electrode 50 may be formed by materials other than the above-listed materials.

In the organic electroluminescent device 110, the first region in which the plurality of conductive parts 50a overlap the first part 40a on the XY plane is a light emitting area EA. In this example, the organic electroluminescent device 110 has a plurality of light emitting areas EAs. Emitted light EL emitted from the organic light emitting layer 40 (the first part 40a) in the light emitting area EA is externally emitted from the organic electroluminescent device 110 through the first electrode 20 and the first support board 10. Part of the emitted light EL is reflected at the second electrode 50 and emitted externally through the organic light emitting layer 40, the first electrode 20, and the first support board 10. That is, in this example, the organic electroluminescent device 110 is a single-surface light-emitting device. In the first region, i.e., the light emitting area EA, a portion where the insulation part 30b is provided does not emit light; however, it is difficult to visually recognize this portion. This portion is part of the light emitting area EA, and light emitted from the perimeter of the portion is diffused in the portion.

In the organic electroluminescent device 110, external light OL applied from the outside penetrates between the plurality of conductive parts 50a. The portion between the plurality of conductive parts 50a is the second region. The organic electroluminescent device 110 emits emitted light EL while allowing external light OL applied from the outside to pass through. The organic electroluminescent device 110 has translucent properties. Through these properties, a background image can be viewed through the organic electroluminescent device 110 from the non-light emitting surface. That is, the organic electroluminescent device 110 is a light source of a see-through thin film or plate.

According to this embodiment, an organic electroluminescent device having a translucent property can be provided. Applying this organic electroluminescent device 110 to a lighting apparatus increases various new applications because of the function of transmitting a background image along with a lighting function.

There may be a case where an organic light emitting layer 40 is provided on the first electrode 20, and the second electrode 50 is provided on the organic light emitting layer 40, without providing the insulation layer 30 in a translucent organic electroluminescent device. With such a configuration, the light emitting area EA of the organic light emitting layer 40 may be damaged when forming the second electrode 50, for example. Specifically, when an evaporation method is used for forming the second electrode 50, a mask (for example, a metal mask) to pattern the second electrode 50 is in contact with and may damage the organic light emitting layer 40. If the light emitting area EA is damaged, the first electrode 20 and the second electrode 50 are in direct contact, and a short-circuit may occur. For example, when using the second electrode 50 with a stripe pattern, a defect due to a dark line may occur. This decreases the organic electroluminescent device's yield.

To avoid the mask damaging the organic light emitting layer, it may be possible to provide an insulation layer at an area other than the light emitting area EA. However, such a method may need alignment of the mask and the insulation layer 30 when forming the second electrode 50. If the alignment is not performed with high precision, the mask may damage the organic light emitting layer, and a short-circuit may occur between the first electrode and the second electrode.

In the organic electroluminescent device 110 according to the embodiment, there is no need to align the mask and the insulation layer 30 when forming the second electrode 50. That is, since the insulation layers 30 are provided uniformly on the first electrode 20, the second electrode 50 can be formed with a mask provided at a discretionary position.

In the translucent organic electroluminescent device, it is preferable to set the width of the conductive part 50a of the second electrode 50 to be narrow so that the second electrode 50 cannot be easily viewed. On the other hand, if the width of the conductive part 50a is too narrow, the light emitting area is decreased, and the light emitting luminance also decreases. For example, there is a method to narrow the width of the conductive part 50a and to narrow the pitch so that the conductive part 50a cannot be easily viewed while obtaining a suitable light emitting luminance.

When adopting such a method, the mask pattern forming the insulation layer 30 and the second electrode 50 becomes fine, and it is difficult to align them. According to the embodiment, since there is no need to perform alignment, it is possible to facilitate manufacturing an organic electroluminescent device with high quality while realizing low manufacturing loss.

In addition, if the mask pattern is fine, the strength of the mask may be lowered, and it is likely that the mask is in contact with the organic light emitting layer 40. If the mask is provided away from the organic light emitting layer 40, the material to be evaporated is diffused after passing through the mask; accordingly, the manufacturing precision of the second electrode 50 may be lowered. Thus, it is not possible to form the second electrode 50 with a desired pattern.

However, the upper surface 40u of the first part 40a of the organic light emitting layer 40 is placed below the upper surface 30u of the insulation layer 30. With this structure, the organic electroluminescent device 110 according to the embodiment realizes that even if the mask is in contact with the second part 40b or the third part 40c of the organic light emitting layer 40, the mask is never in contact with the first part 40a when forming the second electrode 50. That is, the insulation layer 30 acts as a anti-contact layer of the mask when forming the second electrode 50. This structure suppresses damaging the first part 40a, which is a light emitting area EA of the organic light emitting layer 40. Accordingly, the yield of the organic electroluminescent device 110 can be improved, for example. The organic electroluminescent device 110 may also improve reliability, for example. For example, conductive part 50a with a narrow width may be formed with high precision.

If the organic light emitting layer 40 includes a positive hole injection layer and/or a positive hole transport layer, such layers may be provided between the light emitting layer and the first electrode 20. If the organic light emitting layer 40 includes an electron injection layer and/or an electron transport layer, such layers may be provided between the light emitting layer and the second electrode 50.

For example, Alq₃ (tris(8-hydroxyquinolinolato) aluminum, F8BT (poly (9,9-dioctylfluorene-co-benzothiadiazole), and PPV (polyparaphenylene vinylene) may be applied to a light emitting layer. A mixture of a host material and a dopant added to the host material may be used for the first layer 31. For example, CBP (4,4′-N,N′-bis-di carbazolylphenyl rules-biphenyl), BCP (2,9-dimethyl-4,7-diphenyl-1,10-phenanthroline), TPD (4,4′-bis-N-3-methyl-phenyl-N-phenylamino biphenyl), PVK (polyvinyl carbazole), and PPT (poly (3-phenyl-thiophene)) may be used as a host material. For example, Flrpic (iridium (III) bis (4,6-di-fluoro phenyl)-pyridinate-N, C2′-picolinate), Ir(ppy)₃ (tris (2-phenylpyridine) iridium) and Flr6 (bis (2,4-difluorophenyl pyridinato)-tetrakis (1-pyrazolyl) borate-iridium (III)) may be used as a dopant material. The light emitting layer may be formed by materials other than the above-listed materials.

For example, the positive hole injection layer includes at least one of PEDPOT: PPS (poly (3,4-ethylenedioxythiophene)-poly (styrenesulfonate)), CuPc (copper phthalocyanine), and MoO₃ (molybdenum trioxide). For example, the positive hole transport layer includes at least one of α-NPD (4,4′-bis[N-(1-naphthyl)-N-phenylamino]biphenyl), TAPC (1,1-bis[4-[N,N-di (p-tolyl) amino]phenyl]cyclohexane), m-MTDATA (4,4′,4″-tris[phenyl (m-tolyl) amino]triphenylamine), TPD (bis (3-methylphenyl)-N,N′ diphenyl benzidine), and TCTA (4,4′,4″-tris(N-carbazolyl) triphenylamine). When the positive hole injection layer and the positive hole transport layer are used, they may be stacked. The positive hole injection layer and the positive hole transport layer may be formed by materials other than the above-listed materials.

The electron injection layer, for example, includes at least one of lithium fluoride, cesium fluoride, and lithium quinoline complex. The electron transport layer, for example, includes at least one of Alq3 (tris (8-quinolinolato) aluminum (III)), BAlq (bis (2-methyl-8-kinorirato) (p-phenylphenolato) aluminum), Bphen (bathophenanthroline), and, 3TPYMB (tris[3-(3-pyridyl)-mesityl]borane). When the electron injection layer and the electron transport layer are used, they may be stacked. The electron injection layer and the electron transport layer may be formed by materials other than the above-listed materials.

The second support board 80 is formed of a translucent insulation material such as glass, quartz, plastic, and resin. The second support board 80 is formed to face the light emitting area on which the first electrode 20, the organic light emitting layer 40, and the second electrode 50 of the first support board 10 are formed, and is fixed to the first support board 10 by a sealing material (not shown in the drawings) enclosed the light emitting area.

The thickness (length in the Z axis direction) of the first electrode 20 is, for example, 10 nm or more and 500 nm or less. Preferably, the thickness is 50 nm or more and 200 nm or less. The thickness of the insulation parts 30b is, for example, 100 nm or more and 50 μm or less. Preferably, the thickness is 500 nm or more and 10 μm or less. The thickness of the organic light emitting layer 40 is, for example, 50 nm or more and 500 nm or less. The thickness of the second electrode 50 (conductive part 20a) is, for example, 10 nm or more and 300 nm or less. The width W1 (length in the X axis direction) of the conductive part 50a is, for example, 1 μm or more and 1000 μm or less. The pitch Pt1 of the plurality of conductive parts 50a is, for example, 2 μm or more and 2000 μm or less. Preferably, the pitch is 100 μm or more and 1000 μm or less. The pitch Pt1 is the distance between the centers of the adjacent conductive parts 50a in the X axis direction. The width W2 of the insulation parts 30b is, for example, 1 μm or more and 100 μm or less. The pitch Pt2 of the insulation parts 30b is, for example, 2 μm or more and 1000 μm or less.

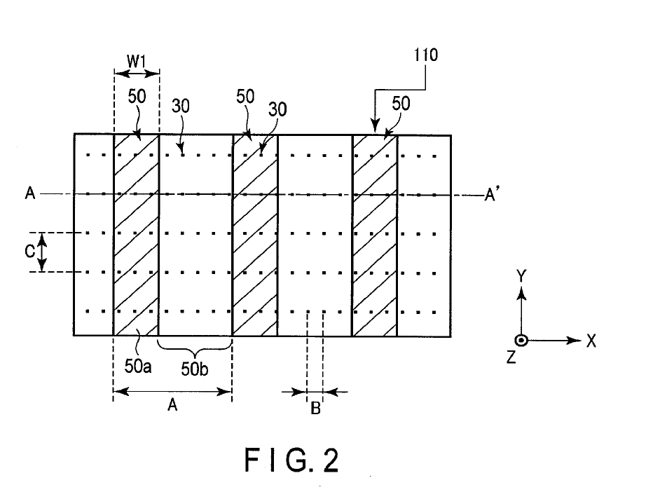

FIG. 2 is a plane figure roughly illustrating an example configuration of the insulation layer 30 and the second electrode 50 in the organic electroluminescent device according to the embodiment.

In the embodiment, the second electrodes 50 are formed on multiple belt-like patterns extending in the second direction Y. The multiple belt-like patterns of the second electrodes 50 are arranged at a predetermined pitch A along the first direction X. The belt-like patterns of the second electrodes 50 are electrically connected to each other at the end of the first support board 10. Part of the first electrode 50 may be extended to the end of the first support board 10 to be connected to a terminal electrically connected to the power supply (not shown in the drawings).

The shape of the second electrode 50 is not limited thereto. The second electrode 50 may have a lattice pattern, and may have a plurality of electrodes extending in the second direction Y as a wave pattern. The belt-like pattern of the second electrode 50 may extend in one direction, and otherwise, multiple patterns extending in different directions may cross each other.

The insulation parts 30b are formed in an island-like pattern, and arranged in the first direction X and the second direction Y. The pitch B that the insulation parts 30b are arranged in the first direction X is narrower than the pitch A that the second electrodes 50 of belt-like pattern are arranged. The pitch C that the insulation parts 30b are arranged in the second direction Y may be the same as or greater than the pitch B that the insulation parts 30b are arranged in the first direction X.

In this example, each of the insulation parts 30b has a cross-sectional shape on the plane essentially parallel to the first direction X and the second direction Y that is circular. The shape of the insulation parts 30b is not limited thereto, and may be a circular, triangular, rectangular, quadrangular, oval, hexagonal, or square pillar.

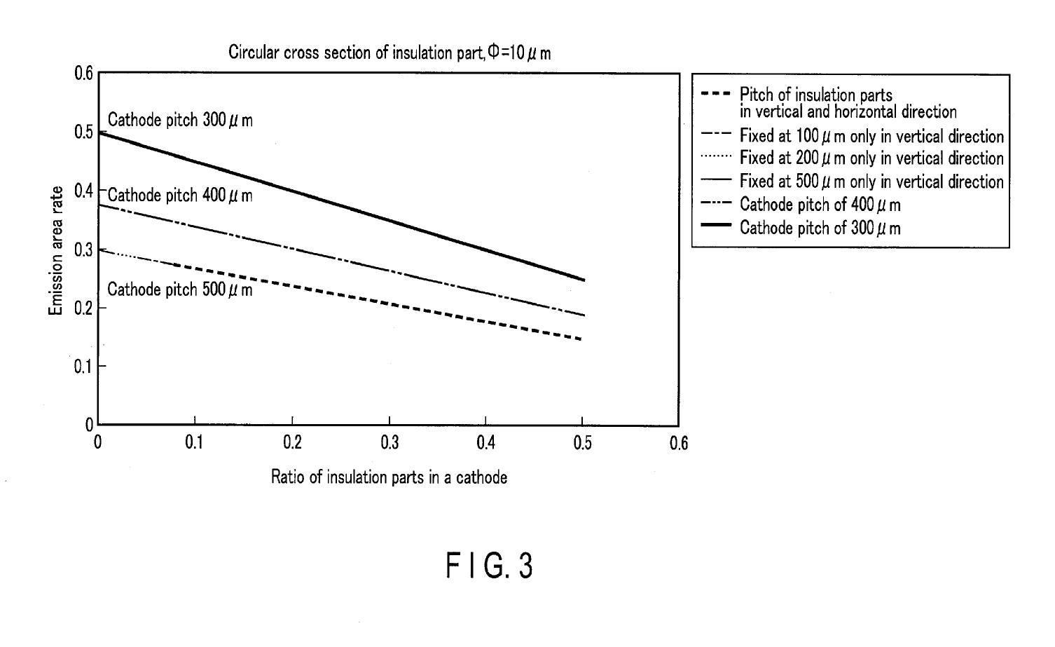

FIG. 3 illustrates an example of the relationship between the covering rate of the insulation layers 30 within the belt-like pattern of the second electrode 50 and the emission surface area rate.

In the example of an organic electroluminescent device explained here, the belt-like pattern of the second electrode 50 has the width of about 150 μm in the first direction X, and the insulation layer 30 has insulation parts 30b in a cylindrical shape. The emission surface area rate is calculated by changing the rate of the surface area where the insulation parts 30b are arranged depending on the change in a diameter size of the insulation parts 30b, the pitch B, and pitch C. The emission surface area rate is the rate of the light emitting area within the surface area of one belt-like pattern of the second electrode 50.

The area where the insulation layer 30 is placed below the second electrode 50 does not emit light. Accordingly, it is preferable that the ratio of the surface area of the insulation layer 30 placed below the second electrode 50 is smaller in order to increase light emitting luminance.

If the ratio of arranging the insulation parts 30b relative to one belt-like pattern of the conductive part 50a of the second electrode 50 is small, the emission surface area rate becomes large; however, it is difficult to support the metal mask used for forming the conductive parts 50a of the second electrode 50 by the insulation layer 30. This may result in damaging the organic light emitting layer 40 due to the metal mask being in contact with the organic light emitting layer 40.

Thus, it is preferable that the ratio of arranging the insulation parts 30b relative to the surface area of one belt-pattern of the conductive part 50a of the second electrode 50 is suitably set to not damage the organic light emitting layer 40, but to obtain a sufficient light emitting area.

Referring to FIG. 3, for example, when a surface area of one belt-like pattern of the second electrode 50 is 1, the ratio of surface area arranging the insulation parts 30b below the second electrode 50 is preferably about 0.001 or more and 0.5 or less (0.1% or more and 50% or less), and is more preferably about 0.01 or more and 0.2 or less (1% or more and 20% or less).

The example of FIG. 3 shows the emission surface area rate for one belt-like pattern of the conductive part 50a of the second electrode 50; however, the example may apply to the emission surface area for all conductive parts 50a of the second electrode 50. That is, for example, when the entire surface area of the conductive parts 50a of the second electrode 50 is 1, the ratio of surface area arranging the insulation parts 30b below the second electrode 50 is preferably about 0.001 or more and 0.5 or less (0.1% or more and 50% or less), and is more preferably about 0.01 or more and 0.2 or less (1% or more and 20% or less).

The emission surface area rate is determined by the width of the second electrode, the pitch of the second electrode, and the arrangement of the insulation layers. For example, the organic electroluminescent device having the second electrode with a width of 150 μm and a pitch of 500 μm and not having the insulation layer 30 exhibits an emission surface area rate of 30%. If the ratio of surface area of the insulation layer 30 is 0.1% or more and 50% or less, the emission surface area rate is 15% or more and 29.97% or less. The emission surface area rate is not limited to the above-listed values. If the emission surface area rate is low, the transmittancy is improved, but the light amount is smaller since the light emission surface area is small. If the emission surface area rate is high, the light amount increases since the light emitting surface area is large, but the transmittancy is lowered. The emission surface area rate may be suitably changed by changing the width, pitch of the second electrode, and the size and arrangement of insulation layers within the range where visibility is ensured and within the range where a suitable light amount is obtained. For example, the emission surface area rate is preferably 10% or more and 70% or less.

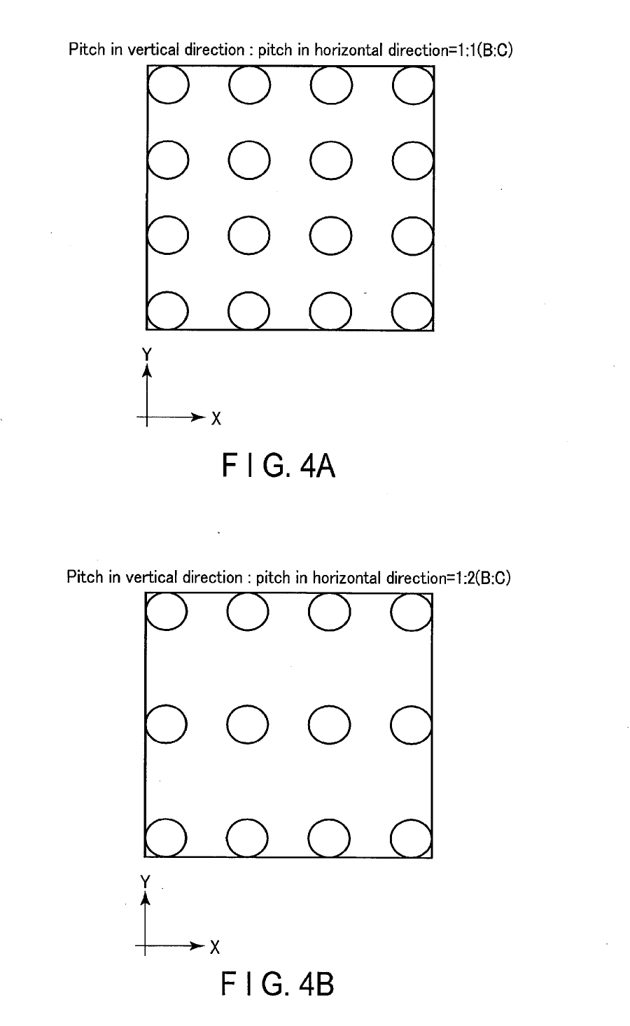

In FIG. 2, the insulation parts 30b are regularly arranged, but may be randomly arranged. In addition, the positions of the insulation parts 30b are not limited to those shown in FIG. 2. FIG. 4A to FIG. 7 illustrate an example of positions where the insulation parts 30b are arranged.

In the example of FIG. 4A, the pitch B of the insulation parts 30b in the first direction X is essentially the same as the pitch C of the insulation parts 30b in the second direction Y. In the example of FIG. 4B, the pitch C of the insulation parts 30b in the second direction Y is around twice the pitch B of the insulation parts 30b in the first direction X. The pitch C may be three times or four times larger than the pitch B.

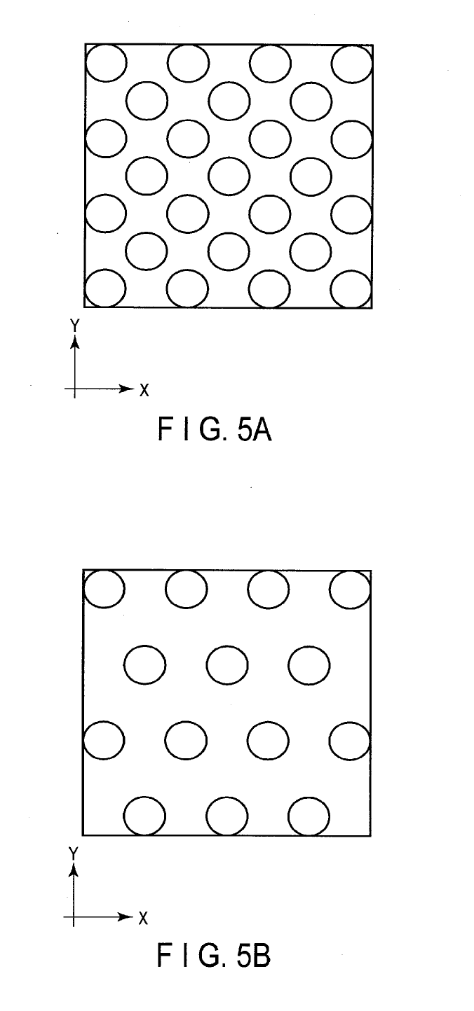

In the example of FIG. 5A, the insulation parts 30b are arranged at the intersections of diagonals connecting the centers of insulation parts 30b arranged in the matrix of two rows in the first direction X and two columns in the second direction Y. In the example of FIG. 5B, the pitch of the insulation parts 30b in the second direction Y is around twice the pitch B of the insulation parts 30b in the first direction X, and the insulation parts 30b are arranged at the intersections of diagonals connecting the centers of insulation parts 30b arranged in the matrix of two rows in the first direction X and two columns in the second direction Y.

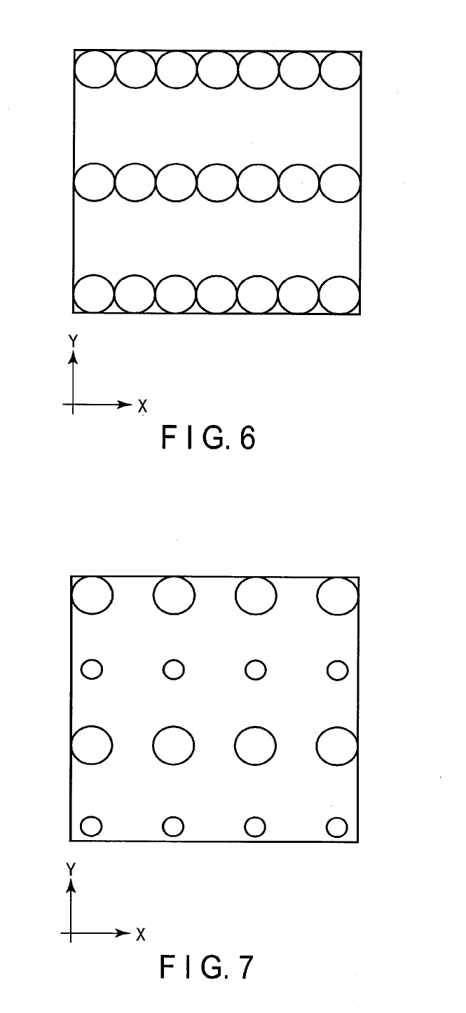

In the example of FIG. 6, the insulation parts 30b arranged in the first direction X are in contact with each other. In this case, the ratio of a surface area where the insulation parts 30b are arranged relative to the surface area of one belt-like pattern of the second electrode 50 becomes large. Accordingly, the insulation parts 30b may be arranged with a high concentration only in an area that needs strength to support a metal mask, for example, while ensuring the visibility of the insulation layers.

In the example of FIG. 7, the pitch B of the insulation parts 30b in the first direction X is essentially the same as the pitch C of the insulation parts 30b in the second direction Y, and the insulation parts 30b of different sizes of circles are alternately arranged in the second direction Y.

For example, if the pitch C is larger than the pitch B, the insulation parts 30b of different sizes may be arranged in an area that needs strength to support a metal mask.

It is preferable to decrease the width of the second electrode 50 in the first direction X, and to decrease the pitch A of belt-like patterns of the second electrodes 50 in the first direction X, so as to make viewing the second electrodes 50 difficult.

The insulation parts 30b may be arranged in the two directions, for example, as in a lattice pattern. Otherwise, the insulation parts 30b may be arranged in the two directions, for example, as in a hexagonal lattice pattern. If the insulation parts 30b are arranged in a lattice pattern, the pitch of arranging the insulation parts 30b in a certain direction and the pitch in another direction may be 1:1 to 1:3, for example. The adjacent insulation parts 30b may be in contact with each other. The insulation parts 30b may be different in size. Two or more insulation parts 30b are covered with the second electrode 50 in the width direction of the conductive parts 50b of the second electrode 50.

If the insulation parts 30b extend in the second direction Y as multiple belt-like patterns, the conductive parts 50a are arranged between the insulation parts 30b, and the area between the insulation parts 30b will be light emitting areas. In other words, an area where the insulation part 30b overlaps the conductive part 50a does not contribute to light emission. The area does not contribute to transmittancy when the conductive part 50a is formed of a light-reflective material. In such an organic electroluminescent device, if the belt-like patterns of the conductive parts 50a are mis-aligned, a light emitting area is not formed between the insulation parts 30b, and as a result, sufficient light emitting areas cannot be obtained. Since the conductive part 50a is formed by evaporating an electrode material through a metal mask, fine alignment is necessary. In addition, if the pitch A of the belt-like patterns of the second electrodes 50 in the first direction X is narrower, the width and the pitch of the belt-like patterns of the insulation parts 30b in the first direction X should be narrower, which results in decreasing clearness of a transmitted image since light passing through an opening of the second electrode 50 is diffracted by the cyclic structure of the second electrodes 50 and the insulation parts 30b.

According to the organic electroluminescent device of the present embodiment, alignment between the belt-like patterns of the second electrodes 50 and the insulation parts 30b is unnecessary by forming the insulation parts 30b in an island pattern, and a mask alignment mechanism with high precision may be unnecessary.

In addition, forming the insulation parts 30b in an island pattern, instead of cyclically forming the second electrodes 50 and the insulation parts 30b, decreases blurriness of a transmitted image due to diffraction of light passing through an opening of the second electrode 50. As a result, visibility is improved.

Furthermore, the area where the insulation parts 30b are placed below the second electrode 50 does not contribute to light emission or light penetration. Accordingly, such an area is preferably set to be smaller to improve visibility and increase the light emission area. In the present embodiment, the number or areas of arranging the insulation parts 30b of the insulation layer 30 can be suitably adjusted, thereby adjusting the areas where the insulation parts 30b of the insulation layer 30 are placed below the second electrode 50. With the above structure, it is possible to decrease the occurrence of non-light emitting parts or non-light penetration parts.

For example, if the insulation layer 30 is formed of a material of low barrier properties against oxygen or water, such as polyimide, the organic light emitting layer 40 may easily be deteriorated due to oxygen or water through the insulation layer 30. However, if the insulation layers 30 are distributed in an island pattern, the organic light emitting layer 40 may not easily be deteriorated. For example, if the width and the pitch of the second electrode 50 is equalized, the organic electroluminescent device shown in FIG. 2 can suppress deterioration due to water or oxygen, and can ensure reliability.

FIG. 8 is a schematic cross-sectional view of another organic electroluminescent device according to the first embodiment. As shown in FIG. 8, the organic electroluminescent device 120 further includes a first support board 10, a second support board 80, and a sealing part 85. The first electrode 20 is provided on the first support board 10. The second support board 80 faces the first support board 10. The second support board 80 has a translucent property. In this example, the configuration of the stacked body SB is the same as that explained with regard to the organic electroluminescent device 110. For example, the stacked body SB includes the first electrode 20, the insulation layer 30, the organic light emitting layer 40, and the second electrode 50. The configuration of the stacked body SB is not limited thereto.

The sealing part 85 is provided in an annular shape along the outer edge of the first support board 10 and the second support board 80 to bond the first support board 10 and the second support board 80. By means of the sealing part 85, the stacked body SB is sealed by the first support board 10 and the second support board 80. In the organic electroluminescent device 120, the distance between the first support board 10 and the second support board 80 in the Z axis direction is defined by the sealing part 85. This configuration can be accomplished, for example, by adding a granular spacer to the sealing part 85. For example, if a plurality of granular spacers are distributed in the sealing part 85, the distance between the first support board 10 and the second support board 80 is defined by the radius of the spacers.

The thickness of the sealing part 85 of the organic electroluminescent device 120 is, for example, 1 μm or more and 50 μm or less. The thickness is preferably, 5 μm or more and 30 μm or less, for example. With this thickness, it is possible to suppress, for example, water and oxygen from entering. The thickness of the sealing part 85 is substantially the same as the spacer radius distributed in the sealing part 85.

An inert gas, for example, is filled with the space between the stacked body SB and the second support board 80. For example, N2 or Ar may be used as the inert gas. A drying material or a desiccant may be provided between the stacked body SB and the second support board 80. An air layer may be provided in the space between the stacked body SB and the second support board 80. A liquid acrylic resin or an epoxied resin, for example, may be filled with the space between the stacked body SB and the second support board 80. An calcium oxide or a barium oxide may be added to the liquid acrylic resin or the epoxied resin as a drying material.

An intermediate layer including a desiccant material may be provided between the stacked body SB and the second support board 80. The intermediate layer may have an oxygen adsorption property. For example, calcium oxide, silica, zeolite, or barium oxide may be used as a desiccant material. The desiccant material is dispersed in the resin material, for example. An acrylic resin, triazine resin, silicon resin, or epoxide resin may be used as a resin material, for example. The intermediate layer includes a resin material. By this structure, it is possible to suppress the substrate 42 contacting the stacked body SB and damaging the stacked body SB when bonding the substrates 40 and 42.

By filling a desiccant material, oxygen absorption material, or an inert gas between the stacked body SB and the second support board 80, it is possible to suitably suppress deterioration of the organic light emitting layer due to oxygen or due to water entering into an element.

For example, a glass substrate or a resin substrate may be used as the second support board 80. The material of the second support board 80 is not limited to that listed above, and may be a material having a mechanical strength to support the stacked body SB. For example, a ultraviolet curing resin may be used as the sealing part 85.

FIG. 9 is a schematic diagram illustrating an example configuration of a lighting system according to the second embodiment.

The lighting apparatus of the present embodiment includes an organic electroluminescent device 130 according to the first embodiment, and a power supply E electrically connected to the first electrode (anode) 20 and the second electrode (cathode).

The lighting system of the present embodiment includes a plurality of organic electroluminescent devices each corresponding to the organic electroluminescent device 130 connected in series or in parallel, instead of the organic electroluminescent device 130 shown in FIG. 9 alone, a first electrode (anode) 20, and a power supply E electrically connected to the first electrodes (anode) 20 and the second electrodes (cathode).

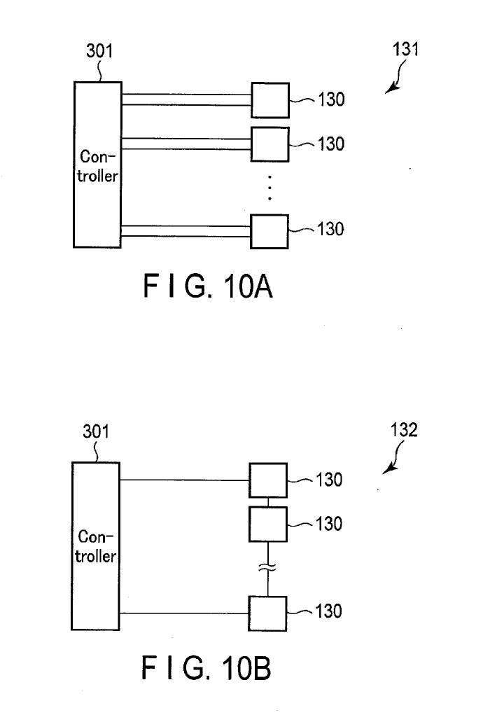

FIGS. 10A and 10B are schematic diagrams showing a lighting system according to the third embodiment.

As shown in FIG. 10A, the lighting system 131 according to the embodiment includes a plurality of organic electroluminescent devices (for example, organic electroluminescent devices 130) according to the first embodiment, and a controller 301.

The controller 301 is electrically connected to each of the plurality of organic electroluminescent devices 130, and controls turning on and off the plurality of organic electroluminescent devices 130. The controller 301, for example, is electrically connected to the first electrode 20 and the second electrode 50 of each of the plurality of organic electroluminescent devices 130. With this structure, the controller 301 individually controls turning on and off the plurality of organic electroluminescent devices 130.

As shown in FIG. 10B, in the lighting system 132, the plurality of organic electroluminescent devices (for example, the organic electroluminescent devices 130) are connected in series with each other. The controller 301 is electrically connected to the first electrode 20 of one of the plurality of organic electroluminescent devices 130. The controller 301 is electrically connected to the second electrode 20 of the other one of the plurality of organic electroluminescent devices 130. With this structure, the controller 301 integrally controls turning on and off the plurality of organic electroluminescent devices 130. Accordingly, the controller 301 may control turning on and off the plurality of organic electroluminescent devices 130 individually or integrally.

According to the present embodiment, a lighting system having high quality and high reliability such as the lighting systems 131 and 132 can be provided in the same way as the organic electroluminescent device and the lighting apparatus stated above.

In the lighting apparatus and the lighting system, a switch SW to switch electrical connections between the power supply E and the organic electroluminescent device OLED may be suitably provided.

As stated above, according the embodiments, an organic electroluminescent device, a lighting apparatus, and a lighting system having high quality can be provided.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

In addition, a technically implementable combination of two or more elements explained above may be included within the scope of the inventions without departing from the spirit of the inventions.

All organic electroluminescent devices, lighting apparatuses, and lighting systems that may be implemented by a person skilled in the art based on the organic electroluminescent device, lighting apparatus, and lighting system explained in the embodiments by changing the design may be included within the scope of the inventions without departing from the spirit of the inventions.

Various modifications or collections may be conceived by a person skilled in the art within the spirit of the inventions, and such modifications or collections may be included in the scope of the inventions.

1. An organic electroluminescent device comprising: a first electrode that is optically transparent and has a first region and a second region;
an insulation layer that has a plurality of insulation parts formed of a translucent insulation material on the first and second regions, wherein the insulation parts arranged per unit of surface area are equal in number between the first and second regions;
an organic layer provided on at least the first region of the first electrode via the insulation layer; and
a second electrode formed on the organic layer, having a plurality of conductive parts each of which is light-reflective and a plurality of openings, wherein each of the openings overlaps at least two of the insulation parts.

2. The organic electroluminescent device according to claim 1, wherein a ratio of a surface area where the conductive parts of the second electrode overlap the insulation parts relative to a surface area of the conductive parts of the second electrode is 0.1% or more and 50% or less.

3. The organic electroluminescent device according to claim 2, wherein a ratio of a surface area where the conductive parts of the second electrode overlap the insulation parts relative to a surface area of the conductive parts of the second electrode is 1% or more and 20% or less.

4. The organic electroluminescent device according to any one of claim 1, wherein the plurality of conductive parts of the second electrode are arranged with an interval in a first direction, and extend in a second direction intersecting the first direction.

5. The organic electroluminescent device according to claim 4, wherein a pitch for arranging the insulation parts in the first direction is smaller than a pitch for arranging the conductive parts of the second electrode.

6. A lighting apparatus comprising:
an organic electroluminescent device according to any one of claim 1; and
a power supply electrically connected to the first electrode and the second electrode.

7. A lighting system comprising:
a plurality of organic electroluminescent devices each corresponding to the organic electroluminescent device according to any one of claim 1; and
a power supply electrically connected to the first electrode and the second electrode of each of the plurality of organic electroluminescent devices.
